(19) United States
(12) Patent Application Publication
(10) Pub. No.: US 2004/0255864 A1
(43) Pub. Date: Dec. 23, 2004

(54) ICP antenna and plasma generating apparatus using the same

(75) Inventors: Sang-Jean Jeon, Suwon city (KR); Jin-Hyuk Choi, Suwon city (KR); Sang-Chul Han, Suwon city (KR); Myoung-Woon Kim, Seoul City (KR); Hyung-Chul Cho, Suwon city (KR)

Correspondence Address: STAAS & HALSEY LLP, SUITE 700, 1201 NEW YORK AVENUE, N.W., WASHINGTON, DC, 20005, US

(73) Assignee: Samsung Electronics Co., Ltd., Suwon-si (KR)

(21) Appl. No.: 10/805,369

(22) Filed: Mar. 22, 2004

(30) Foreign Application Priority Data
Jun. 18, 2003 (KR) 2003-39365

(51) Int. Cl. C23C 16/00

(52) U.S. Cl. 118/723 I

(57) ABSTRACT

An inductively-coupled antenna (ICP) in a plasma generating apparatus comprises an inner antenna segment having an annular shape and at least one outer antenna segment approximately concentrically placed outside of the inner antenna segment, and connected to the inner antenna segment in series, wherein at least one of the inner antenna segments and the outer antenna segments have a plurality of annular coils connected in parallel with each other and having a different diameter from each other. Accordingly, the present invention provides an ICP antenna and plasma generating apparatus using the same having a simple structure, a reduced inductance, and an improved uniformity of plasma density.

### CROSS-REFERENCE TO RELATED APPLICATIONS

This application claims the benefit of Korean Patent Application No. 2003-39365, filed Jun. 18, 2003, in the Korean Intellectual Property Office, the disclosure of which is incorporated herein by reference.

### BACKGROUND OF THE INVENTION

1. Field of the Invention

The present invention relates to an inductively-coupled plasma (ICP) antenna and a plasma generating apparatus using the same, and more particularly, to an ICP antenna and a plasma generating apparatus using the same having improved plasma generating characteristics providing a simple structure, a reduced inductance and an improved uniformity of plasma density.

2. Description of the Related Art

In semiconductor manufacturing processes, such as for producing wafers or flat display devices, various surface finishing processes such as an etching process, a CVD (Chemical Vapor Deposition) process, a sputtering process, and so on, are conducted using gaseous plasma. In general, plasma is created from a gas in a low-pressure environment generated by free electrons ionizing each of the gas-particles having kinetic energy transferred by electric field ionization and collision of each of the electrons and the gas-particles. As a result, the electrons are accelerated in an electric field, typically in a high frequency.

There are many methods to accelerate electrons in a high frequency electric field. For example, U.S. Pat. No. 4,948,458 discloses a plasma generating apparatus which triggers electrons to be excited at the high frequency electric field in a chamber using a planar antenna coil on a side of semiconductor wafer.

FIG.1 illustrates a planar spiral coil of an antenna system in U.S. Pat. No. 4,948,458. As shown in FIG. 1, the flat-typed spiral coil comprises a single conductor formed with the planar spiral, and is connected to a high frequency tap to be connected with a high frequency circuit. Such a planar spiral coil provides a circular current pattern and the circular current generates annular plasma which can trigger a radial disuniformity in the wafer by turns. That is, the electric field inductively generated by the antenna formed in the planar spiral coil typically has an azimuth angle, but its center has a value of zero. That means, the antenna generates the annular plasma having a low pressure in a middle of the antenna, and has to depend on plasma diffusion (diffusion of electron and ion toward a center) to provide equal uniformity. However, certain applications create imperfect uniformity of the plasma diffusion. Also, the single planar spiral coil only has a series connection resulting in a high impedance of the antenna creating a surge of high voltage likely causing an arc. Furthermore, unstable plasma and discharge of particles having a capacitive coupling with the plasma may result.

On the other hand, PCT International Publication No. WO 2000/00993 discloses an antenna system having two planar coils connected in parallel. FIG. 2 illustrates the antenna system disclosed in PCT International Publication No. WO 2000/00993. As shown in FIG. 2, the antenna system disclosed in PCT International Publication No. WO 2000/00993 has two single wired coils 210 and 211. A coil 210 (to be called “inner coil”, hereinafter) is located in a middle area, and the other coil 211 (to be called “outer coil”, hereinafter) is located outside toward a corner of an upper opening part of a reactor. A high frequency current is simultaneously provided at the ends of the inner coil 210 and the outer coil 211 via synchronizing capacitors C1 and C2. The high frequency input is generated from a high frequency power source 220 and provided to the capacitors C1 and C2 via a high frequency matching network 221. The synchronizing capacitors C1 and C2 respectively control an amount of currents I1 and I2 in the inner coil 210 and the outer coil 211. Also, the other ends of the inner coil 210 and the outer coil 211 are connected to each other and grounded to impedance (ZT). Herein, the antenna generates the annular plasma having a diameter almost half the size of the diameter of the coil. Thus by placing the inner coil 210 and the outer coil 211 separately, the antenna efficiently generates a progressive annular plasma having a diameter approximately half of an average diameter of the two coils. Such an antenna in parallel connection has the benefit of reducing the coil's inductance. But on the other hand, the antenna requires the capacitors C1 and C2 to be installed. If the capacitors C1 and C2 are removed, the high frequency power flows through the inner coil 210 because the two coils are connected in parallel and the inner coil's 210 inductance gets smaller since the diameter of inner coil 210 diameter is smaller than that of the outer coil. Therefore, the cost of structuring and manufacturing increases because the antenna has to comprise the capacitors C1 and C2 to provide the uniformity of the plasma.

### SUMMARY OF THE INVENTION

Accordingly, it is an aspect of the present invention to provide an ICP antenna and plasma generating apparatus which create highly improved uniform plasma and reduce inductance in the antenna by providing a stable plasma.

The foregoing and/or other aspects of the present invention are achieved by providing an inductively-coupled antenna (ICP) used for a plasma generating apparatus including an inner antenna segment in annular shape, and at least one outer antenna segment approximately concentrically placed outside of the inner antenna segment, and connected to the inner antenna segment in series, and at least one of the inner antenna the outer antenna having a plurality of annular coils connected in parallel to each other and having a different diameter from each other.

According to an aspect of the invention, the inner antenna segment and the outer antenna segment have currents respectively flowing along the same circumferential direction of each other.

According to an aspect of the invention, the inner antenna segment and the outer antenna segment have currents respectively flowing along the opposite circumferential direction of each other.

According to an aspect of the invention, at least one of the outer antenna segments has current flowing along the opposite circumferential direction to the current directions of the rest of the outer antennas.

According to an aspect of the invention, the annular coils of the inner antenna segment and the outer antenna segment have a pipe shape.

According to an aspect of the invention, the pipe shaped antenna coils of the inner antenna segment and the outer antenna segment are connected to each other as a whole.

According to another aspect of the present invention, the foregoing and/or other aspects may be also achieved by providing a plasma generating apparatus having a chamber accommodating an object to be processed, and a window plate forming an electric field circuit in the chamber, comprising an inductively-coupled plasma (ICP) antenna having an inner antenna segment placed near the window plate having an annular shape and at least one outer antenna segment approximately concentrically placed outside of the inner antenna segment connected to the inner antenna segment in series, and a high frequency power supply supplying a high frequency power to the ICP antenna and at least one of the inner antenna segment and the outer antenna segment having a plurality of annular coils different in diameters and connected in parallel to each other.

According to an aspect of the invention, the plasma generating apparatus further comprises a grounding plate to which a ground end of the ICP antenna is grounded.

According to an aspect of the invention, the inner antenna segment and the outer antenna segment are formed by a pipe shaped annular coil as a whole.

According to an aspect of the invention, the plasma generating apparatus further comprises a cooling water supplier supplying cooling water into the pipe shaped coil of the ICP antenna in an area near where the ICP antenna is grounded to the grounding plate.

According to another aspect of the present invention, the foregoing and/or other aspects may be also achieved by providing an ICP antenna for a plasma generating apparatus, including a plurality of antenna segments approximately concentrically placed and connected in series with each other, and wherein at least one of the plurality of antenna segments has a plurality of annular coils connected in parallel to each other, and being approximately concentrically placed from each other.

Additional aspects and/or advantages of the invention will be set forth in part in the description which follows and, in part, will be obvious from the description, or may be learned by practice of the invention.

### BRIEF DESCRIPTION OF THE DRAWINGS

These and/or other aspects and advantages of the invention will become apparent and more readily appreciated from the following description of the embodiments taken in conjunction with the accompanying drawings in which:

FIG. 1 is a drawing illustrating an antenna system formed by a single wired coil used for a conventional plasma generating apparatus;

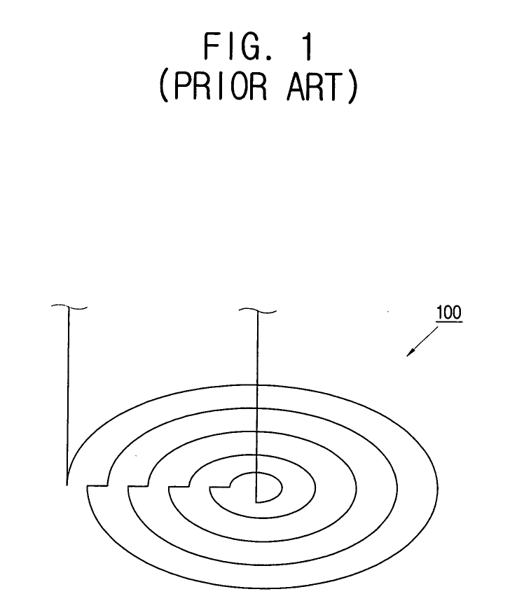

FIG. 2 is a drawing illustrating the antenna system formed by double parallel structured coils used for the conventional plasma generating apparatus;

FIG. 3 is a drawing illustrating a schematic configuration of a plasma generating apparatus of the present invention;

FIG. 4 is a drawing illustrating a composition of ICP antenna according to a first embodiment of the present invention;

FIG. 5 is drawing illustrating a magnetic field formed by the composition of ICP antenna as shown in FIG. 4;

FIG. 6 is a drawing illustrating the composition of ICP antenna according to a second embodiment of the present invention;

FIG. 7 is a drawing illustrating the ICP antenna grounded to a grounding plate according to the first embodiment of the present invention.

### DETAILED DESCRIPTION OF THE PREFERRED EMBODIMENTS

Reference will now be made in detail to the embodiments of the present invention, examples of which are illustrated in the accompanying drawings, wherein like reference numerals refer to the like elements throughout. The embodiments are described below to explain the present invention by referring to the figures.

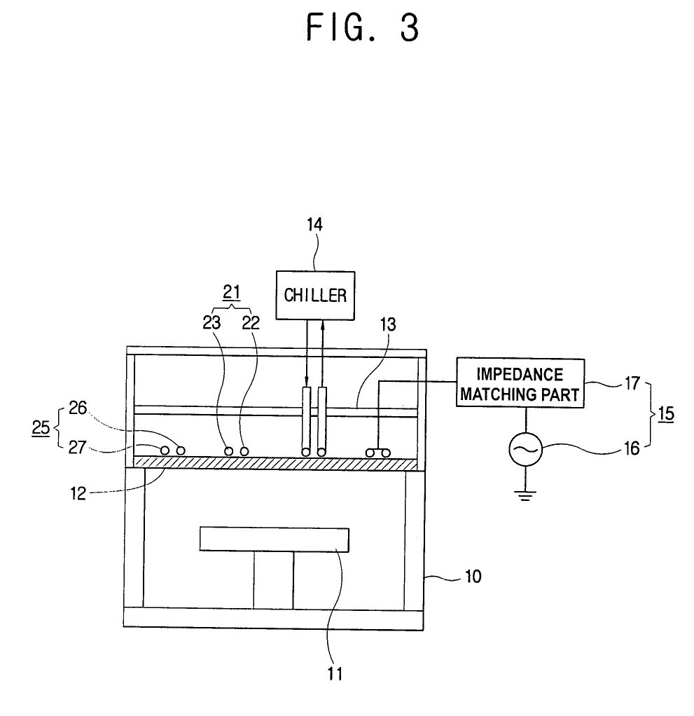

As illustrated in FIG. 3, a plasma generating apparatus according to the present invention, comprises a closed chamber 10, a window plate 12 for forming a path of a magnetic field towards the inside of the chamber 10, an ICP antenna 20 disposed near an upper side of the window plate 12, and a high frequency power supply 15 supplying high frequency powers to the ICP antenna 20.

The chamber 10 has an electromagnetic chuck 11 inside, and the chuck works as an electrode and supports an object to be processed such as a wafer and the like. The window plate 12 forms an upper plate of the chamber to be closed, and allows formation of the path of the magnetic field generated from the ICP antenna 20.

The high frequency power supply 15 comprises a high frequency generating part 16 generating, for example, 13.56 MHz high frequency, and a matching part 17 transferring the high frequency from the high frequency power supply 15 to a powered end of the ICP antenna 20.

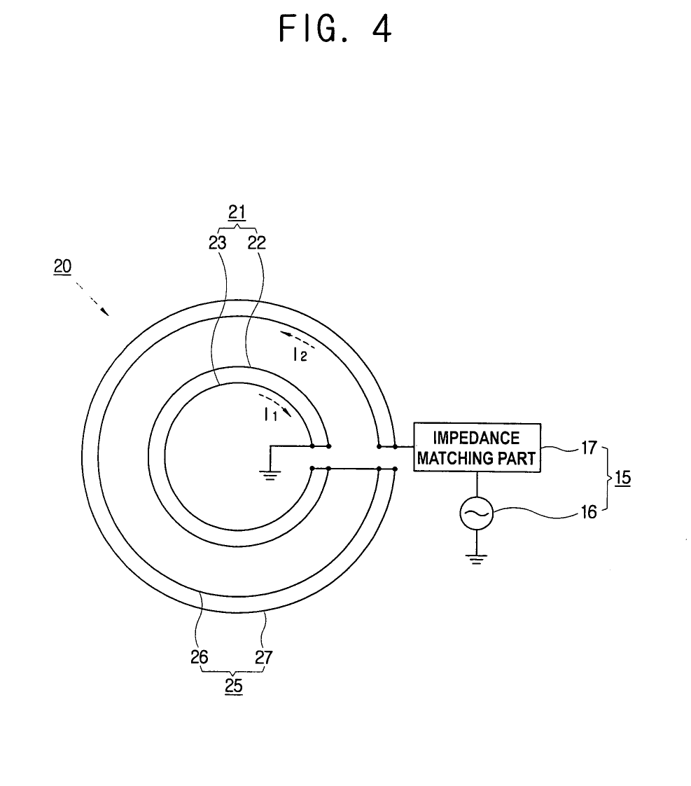

As shown in FIG. 4, the ICP antenna 20, according to the first embodiment of the present invention, has an annular inner antenna segment 21 and at least one annular outer antenna segment 25 connected to the inner antenna segment in series, and approximately concentrically placed outside of the inner antenna segment 21. The ICP antenna 20 having one outer antenna segment according to a first aspect of the present invention will be described hereafter. In another aspect, more than two outer antenna segments having a different diameter from each other and approximately concentrically placed outside of the inner antenna segment 21 are also included in the present invention.

The powered end of the outer antenna segment 25 is connected to the impedance matching part 17, and the ground end of the outer antenna segment 25 is connected to the powered end of the inner antenna segment 21. The ground end of the inner segment 21 is grounded to a grounding plate 13 (to be described later referring to FIG. 3). With this configuration, the inner antenna segment 21 and the outer antenna segment 25 are connected in series to each other.

At least one of the inner antenna segments 21 and the outer antenna segment 25 has a plurality of annular coils having different diameters, and are connected in parallel to each other. The inner antenna segment 21 and the outer antenna segment 25 of the ICP antenna 20 according to the first embodiment of the present invention respectively have a pair of annular coils 22, 23, 26, and 27 connected in parallel to each other.

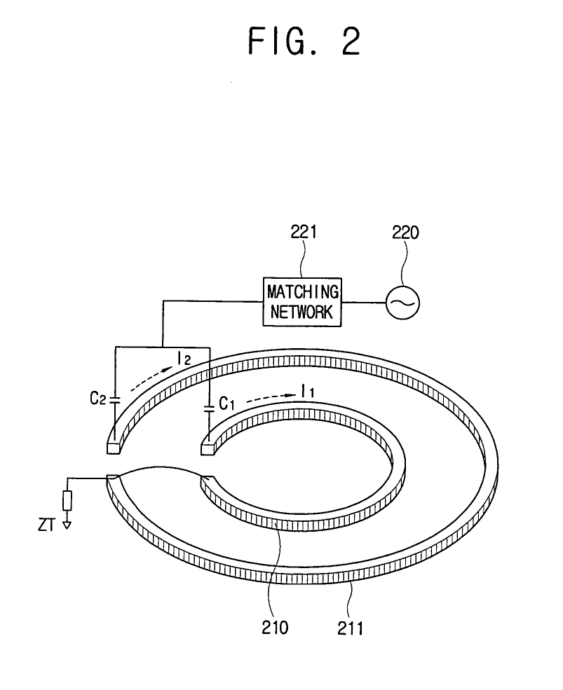

The pair of the annular coils 26 and 27 of the outer antenna coil 25 have different diameters from each other and are approximately concentrically placed. The pair of annular coils 26 and 27 of the outer antenna segment 25 are preferably close to each other. That is, by minimizing the difference in diameter between the pair of annular coils 26 and 27 of the outer antenna segment 25 a difference in inductance of each of the coils 26 and 27 is minimized, thereby equalizing a flow of the high frequency from the matching part 17 to the pair of annular coils 26 and 27 of the outer antenna segment 25. With this configuration, the present invention provides a simple and economic ICP antenna structure since the capacitors (C1 and C2 in FIG. 2) are no longer necessary components for uniformity of the plasma density according to the conventional parallel antenna structure. Also, an inductance decreases, thereby resulting in a reduced charging voltage in the outer antenna segment 25 by having the pair of annular coils 26 and 27 of the outer antenna segment 25 connected in parallel each other.

The inner antenna segment 21 according to the present invention also comprises a pair of annular coils 22 and 23 having different diameters and approximately concentrically placed along each other. Herein, the pair of annular coils 22 and 23 of the inner antenna segment 21 are preferably close to each other like the annular coils of the outer antenna segment 25. Therefore, the uniformity of the plasma density improves by equalizing flow of the high frequency from the ground end of the outer antenna segment 25 to the pair of annular coils of the inner antenna segment 21.

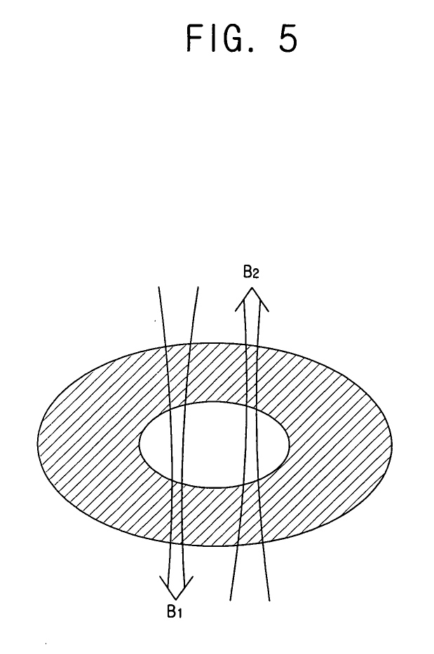

In the ICP antenna 20 according to the present invention, current I1 of the inner antenna segment 21 flows along a circumferential direction and the current I2 of the outer antenna segment 25 flows along the opposite circumferential direction to the current direction of the inner antenna segment 21. That is, the current flowing from the powered end to the ground end in the outer antenna segment 25 flows in a counterclockwise direction, and the current flowing from the powered end to the ground end in the inner antenna segment 21 flows in a clockwise direction, as shown in FIG. 4. Therefore, as shown in FIG. 5, a magnetic field B1 formed by the inner antenna segment 21 and the magnetic field B2 formed by the outer antenna segment 25 are countervailed in a central portion of the ICP antenna 20, thereby causing a weaker inducted electric field or blocking the high frequency with the magnetic field formed in the inner antenna segment 21. Thus, a dashed area, as shown in FIG. 5, having a strong magnetic field, is formed, and thereby the electric field to be inducted forms uniform plasma.

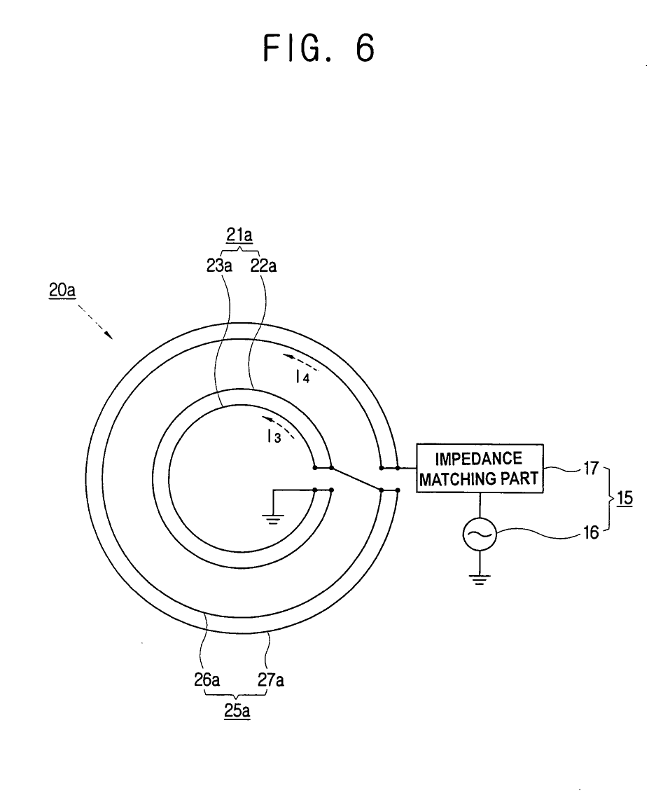

FIG. 6 illustrates a structure of the ICP antenna 20 according to a second embodiment of the present invention. In the ICP antenna 20A in the present invention as shown in FIG. 6, a current I3 of the inner antenna segment 21A flows along a circumferential direction and the current I4 of the outer antenna segment 25A flows along the same circumferential direction with the current direction of the inner antenna segment 21A. That is, the currents flowing from the powered end to the ground end in the inner antenna segment 21A and the outer antenna segment 25A both flow in a counterclockwise direction. Therefore, the strong magnetic field is formed in the central portion of the inner antenna segment 21A, and consequently inducts the strong electric field in the inner antenna segment 21A. Herein, it is preferable that the ICP antenna 20A, according to the second embodiment of the present invention, should be applied to cases that forcefully require plasma in a center area of the object to be processed.

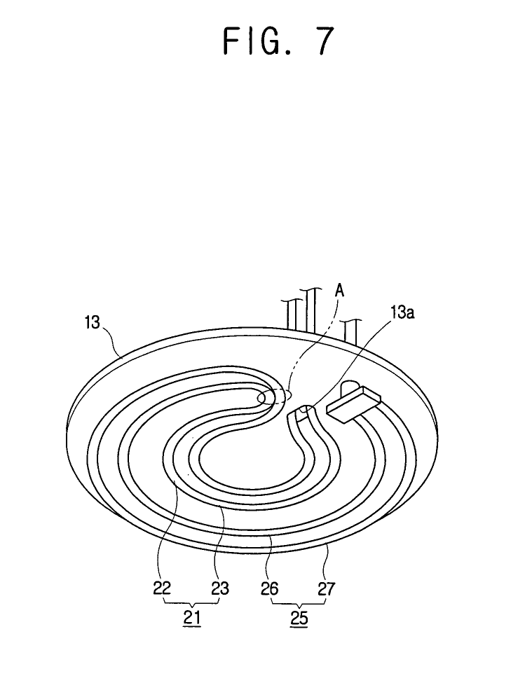

The plasma generating apparatus, according to the present invention, comprises the grounding plate 13 to which the ground end of the ICP antenna 20, or the ground end of the inner antenna segment 21, is grounded. FIG. 7 illustrates grounding of the ICP antenna 20, in the present invention, to the grounding plate 13. As shown in FIG. 7, the grounding plate 13 is of a roundlike type, and placed in an upper area of the ICP antenna 20.

In the present invention, the plasma generating apparatus comprises a cooling water supplier 14 (refer to FIG. 3) supplying a cooling water to cool off the ICP antenna 20. The annular coils of the inner antenna segment 21 and the outer antenna segments 25 in the ICP antenna 20 may be of a pipe type. Hence, the cooling water supplied by the cooling water supplier 14 flows through the pipe-typed coils to efficiently cool off the ICP antenna 20. Herein, the cooling water supplier 14 preferably supplies the cooling water into the pipe-typed coils of the ICP antenna 20 near where the ICP antenna is grounded to the grounding plate 13. With reference to FIG. 3 and FIG. 7, the grounding plate 13 includes a grounding hole 13A for the ground end of the inner antenna segment 21 to pass through. Herein, the ground end of the inner antenna segment 21 is grounded having the ground end touching a side of the grounding hole 13A, and thereby preventing arc discharging where the cooling water is supplied to the ICP antenna 20.

A portion of the ground end of the inner antenna segment 21 passes through the grounding hole 13A of the grounding plate 13 and is extended to be connected to the cooling water supplier 14, and thereby the cooling water flows into the pipe-typed coils of the inner antenna segment 21 from the cooling water supplier 14. Herein, the pipe-typed annular coils of the inner antenna segment 21 and the outer antenna segment 25 are formed and connected by a single pipe, so that the cooling water supplied from the cooling water supplier 14 can flow through the pipe-typed coils forming a closed loop. In area A of FIG. 7, the inner antenna segment 21 and the outer antenna segment 25 respectively having pairs of the annular coils 21, 22, 26 and 27 placed in a double spiral shape contact each other, and thereby the ICP antenna 20 has the inner antenna segment 21 and the outer antenna segment 25 comprising the pair of annular coils (22, 23, 26 and 27) connected in parallel, and in series with each other.

With this configuration, at least either the inner antenna segment 21 or the outer antenna segment 25 has plural annular coils (22, 23, 26, 27, 22A, 23A, 26A, and 27A) connected in parallel. This configuration reduces the whole inductance and improves the uniformity of the plasma for a length of the annular coils (22, 23, 26, 27, 22A, 23A, 26A, and 27A). Provided a same amount of high frequency is supplied to the plural annular coils (22, 23, 26, 27, 22A, 23A, 26A, and 27A) connected in series, a current density decreases compared to the conventional antenna having a single annular coil connected in series, and thereby a resistance proportional to the square currents is remarkably reduced, therefore increasing a usable high frequency power.

The whole inductance in the annular coils connected in parallel is reduced compared to the series connection of conventional structure so as to discharge voltage changed to the ICP antenna.

Having the cooling water supplied from the cooling water supplier 14 to the IPC antenna 20 near where the ICP antenna 20 is grounded to the grounding plate 13, prevents arc discharging through the grounding plate 13 where the cooling water is supplied to the ICP antenna 20 when applying a high frequency voltage to the ICP antenna.

With this configuration, the ICP antenna and the plasma generating apparatus according to the present invention provides highly improved uniform plasma and reduces the inductance in the antenna providing a stable plasma.

Although a few embodiments of the present invention have been shown and described, it will be appreciated by those skilled in the art that changes may be made in these embodiments without departing from the principles and spirit of the invention, the scope of which is defined in the appended claims and their equivalents.

What is claimed is:

1. An inductively-coupled antenna (ICP) used for a plasma generating apparatus comprising:
an inner antenna segment having an annular shape; and
at least one outer antenna segment approximately concentrically placed outside of the inner antenna segment, and connected to the inner antenna segment in series;
wherein the inner antenna segment and the at least one of the outer antenna segments have a plurality of annular coils connected in parallel to each other and have a different diameter from each other.

2. The ICP antenna according to claim 1, wherein the inner antenna segment and the at least one outer antenna segments have currents respectively flowing along the same circumferential direction as each other.

3. The ICP antenna according to claim 1, wherein the inner antenna segment and the at least one outer antenna segment have currents respectively flowing along opposite circumferential directions as each other.

4. The ICP antenna according to claim 1, wherein at least one of the outer antenna segments has current flowing along the opposite circumferential direction of the current directions of the remaining at least one outer antenna segment.

5. The ICP antenna according to claim 1, wherein the annular coils of the inner antenna segment and the at least one outer antenna segment have a pipe shape.

6. The ICP antenna according to claim 5, wherein the pipe shaped antenna coils of the inner antenna segment and the outer antenna segment are connected to each other as a whole.

7. A plasma generating apparatus having a chamber accommodating an object to be processed, and a window plate forming an electric field circuit in the chamber, comprising:
an inductively-coupled plasma (ICP) antenna having an inner antenna segment placed near the window plate having an annular shape, and at least one outer antenna segment approximately concentrically placed outside of the inner antenna segment connected to the inner antenna segment in series; and
a high frequency power supply supplying a high frequency power to the ICP antenna;
wherein the inner antenna segment and the at least one of the outer antenna segments have a plurality of annular coils different in diameters and are connected in parallel to each other.

8. The plasma generating apparatus according to claim 7, further comprising a grounding plate to which a ground end of the ICP antenna is grounded.

9. The plasma generating apparatus according to claim 8, wherein the inner antenna segment and at least one of the outer antenna segments are formed by a pipe shaped annular coil as a whole.

10. The plasma generating apparatus according to claim 9, further comprising a cooling water supplier supplying cooling water into the pipe shaped coil of the ICP antenna in an area near where the ICP antenna is grounded to the grounding plate.

11. An ICP antenna for a plasma generating apparatus comprising:
a plurality of antenna segments approximately concentrically placed and connected in series to each other; wherein at least one of the plurality of antenna segments has a plurality of annular coils connected in parallel to each other, approximately concentrically placed near each other.

12. A plasma generating apparatus comprising:
a chamber accommodating an object to be processed;
a window plate forming an electric field circuit in the chamber;
an inductively-coupled plasma (ICP) antenna comprising an inner antenna segment placed near the window plate, and at least one outer antenna segment approximately concentrically placed outside of the inner antenna segment and connected to the inner antenna segment in series; and
a high frequency power supply supplying a high frequency power to the ICP antenna;
wherein the inner antenna segment and at least one of the outer antenna segments include a plurality of annular coils connected in parallel to each other and having different diameters.

13. The plasma generating apparatus according to claim 12, wherein the window plate has an annular shape.

14. The plasma generating apparatus according to claim 12, wherein the inner antenna segment and the at least one outer antenna segment have currents flowing along same circumferential directions as each other.

15. The plasma generating apparatus according to claim 12, wherein the inner antenna segment and the at least one outer antenna segment have currents flowing along opposite circumferential directions as each other.

16. The plasma generating apparatus according to claim 12, wherein the annular coils of the inner antenna segment and the at least one outer antenna segment have a pipe shape.

17. The plasma generating apparatus according to claim 16, wherein the pipe shaped annular coils of the inner antenna segment and the at least one outer antenna segment are connected to each other as a whole.

18. The plasma generating apparatus according to claim 17, wherein the pipe shaped annular coils of the inner antenna segment and the at least one outer antenna segment are connected to a cooling water supplier.
